(19) United States
(12) Patent Application Publication
(10) Pub. No.: US 2012/0298200 A1
(43) Pub. Date: Nov. 29, 2012

(54) PHOTOVOLTAIC CELL

(75) Inventors: Michael Niggemann, Cambridge (GB); Jurjen F. Winkel, Cambridge (GB)

(73) Assignee: CAMBRIDGE ENTERPRISE LIMITED, Cambridge (GB)

(21) Appl. No.: 13/575,157

(22) PCT Filed: Jan. 25, 2011
(86) PCT No.: PCT/GB2011/050117

§ 371 Date: Jul. 25, 2012

(30) Foreign Application Priority Data
Jan. 25, 2010 (GB) 1001156.7

(51) Int. Cl. H01L 31/0376; H01L 31/02

(52) U.S. Cl. 136/258; 136/252

(57) ABSTRACT

An organic photovoltaic cell (100) having a pair of electrodes (113,114) and a photoactive layer (112) comprising a photoactive material, and means (111) to control and/or regulate the operating temperature of the cell (100).

The invention relates to photovoltaic cells, more specifically although not exclusively organic photovoltaic cells, and modules, apparatuses and devices comprising such cells.

A photovoltaic cell contains a photoactive material which absorbs electromagnetic radiation; the absorbed photonic energy is converted into electrical energy via the photovoltaic effect. Solar cells are photovoltaic cells that convert sunlight into electrical energy.

The development of photovoltaic cells, in particular solar cells, has attracted considerable interest in recent years as society searches for cleaner energy generation technologies.

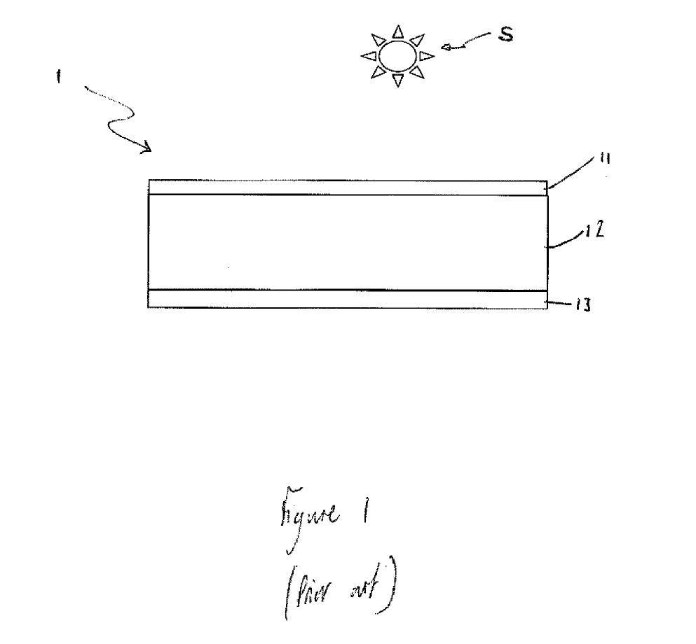

The basic structure of a typical photovoltaic or solar cell is illustrated schematically in cross section in FIG. 1.

A solar cell 1 has the form of a layered structure comprising a transparent electrode 11, a photoactive layer 12 and a back electrode 13.

In operation, electromagnetic radiation from the sun S passes through the front electrode 11 into the photoactive layer 12. Within the photoactive layer 12, photons are absorbed resulting in the generation of electron-hole pairs. The electron-hole pairs are separated within the photoactive layer, with electrons travelling to one electrode, e.g. the front electrode 11, and holes travelling to the other electrode, e.g. the back electrode 13.

Typically, the back electrode 13 may be reflective. An antireflection coating may be applied to a surface of the transparent front electrode 11.

A plurality of cells may be grouped together to form a module. Typically, the cell or module may be encapsulated.

An electrical load may be connected between the front and back electrodes.

Organic, typically polymeric, photoactive materials are being investigated as an alternative to inorganic materials such as silicon, cadmium telluride and gallium arsenide. Also, organic photoactive materials comprising small molecules deposited by vapour deposition techniques are being investigated. Further, photovoltaic systems which utilise both organic and inorganic components have attracted some interest.

Organic photovoltaic cells and modules promise significant advantages in terms of ease and cost of manufacture. A notable advantage is that organic photovoltaic cells or modules can be manufactured using printing or coating methods as thin films on substrates which may be lightweight and/or flexible, thereby easing installation and offering increased versatility.

However, a major drawback is that organic photoactive cells tend to exhibit considerably lower power conversion efficiencies than inorganic photoactive cells. Power conversion efficiency (η) is a measure of the proportion (usually expressed as a percentage) of power converted from incident light energy to electrical energy.

Also, it has been found that organic photovoltaic modules often exhibit an increased or optimum power conversion efficiency in a particular cell temperature range.

However, this optimum cell temperature range may not be or may only very rarely be achieved under the conditions (e.g. ambient temperature, solar irradiance, wind speed) that a photovoltaic module experiences in situ.

It is a first non-exclusive object of the invention to provide a photovoltaic cell which may have a higher power conversion efficiency in situ than prior art cells.

It is a second non-exclusive object of the invention to provide a photovoltaic cell which is adapted to operate within or towards optimum power conversion efficiency in a variety of environmental and/or climatic conditions.

A first aspect of the invention provides a photovoltaic cell, preferably an organic photovoltaic cell, having a pair of electrodes and a photoactive layer comprising a photoactive composite, e.g. a semiconducting polymer, which comprises means to is control and/or regulate the operating temperature of the cell.

The means to control and/or regulate the operating temperature of the cell may comprise means to increase and/or means to decrease the in-use operating temperature of the photoactive layer.

A second aspect of the invention provides a temperature regulating photovoltaic cell, the cell comprising a photoactive layer provided between electrodes, and means to increase and/or means to decrease the in-use operating temperature of the photoactive layer.

The means for increasing and/or decreasing the operating temperature may be active or passive.

Preferably, the cell may be encapsulated.

Advantageously, photovoltaic cells or modules according to the invention may operate in situ within or close to the optimum cell temperature range and, therefore, more efficiently for a greater proportion of a given period of time.

Accordingly, cells according to the invention may convert more light energy into electrical energy over the given period of time than prior art cells.

The cell may comprise a layered structure including a transparent front electrode and a back electrode with the photoactive layer therebetween.

The layered structure may be provided on a transparent superstrate in front of, e.g. adjacent, the transparent front electrode or a substrate behind, e.g. adjacent the back electrode. The superstrate or substrate may be from 5 to 300 μm thick. Thicker superstrates or substrates may also be used, e.g. glass having a thickness of 2 mm or steel foil.

The transparent front electrode may be a cathode and the back electrode may be an anode or vice versa.

The electrodes may have thicknesses of from 20 to 200 nm. Typically, transparent electrodes may have thicknesses towards the lower end of this range. However, screen printed electrodes may be considerably thicker, e.g. up to 20 μm.

The back electrode may be at least partially transparent or reflective.

Preferably, the photoactive layer may have a thickness of from 50 to 500 nm, more preferably from 70 to 350 nm, even more preferably from 100 to 300 nm, most preferably from 100 to 250 nm.

When the cell is encapsulated, an encapsulating layer may be from 5 to 200 μm, e.g. from 5 to 175 μm, preferably from 5 to 100 μm, thick.

At least a portion of the encapsulating layer may be adapted to provide thermal insulation. For instance, the encapsulating layer may comprise glass or a transparent polymer (PET, PC, PMMA), a porous material such as a foam or aerogel and/or a thermally reflective material such as a metallised foil. In embodiments where at least a portion of the encapsulating layer is adapted to provide thermal insulation, the encapsulating layer, or at least a portion thereof, may be relatively thick, e,g. up to 5 mm thick.

Preferably, the cell may be from 450 to 900 nm thick without the or a substrate, superstrate or encapsulation. For instance, including the or a substrate, superstrate or encapsulation, the cell may be from 300 to 700 μm thick. The person skilled in the art will appreciate from the preceding paragraphs that the cell thickness may be outside these ranges.

The photoactive composite may be a blend of a conjugated polymer and a fullerene derivative such as a blend of poly (3-hexylthiophene) and [6,6]-phenyl C₆₁-butyric acid methylester (P3HT:PCBM). P3HT, the main absorber in this photoactive composite has a band gap of around 2.1 eV and absorbs wavelengths of up to around 650 nm.

Alternatively, the photoactive composite may comprise a blend of two conjugated polymers one presenting the donor and one the acceptor.

Other suitable photoactive composites may comprise: p-phenylenevinylene-based conjugated polymers such as (poly(2-methoxy-5-((3′,7′-dimethyloctyl)oxy)-1,4-phenylenevinylene) (MDMO-PPV,); fluorene-based conjugated polymers, e.g. 2,1,3-benzothiadiazole-containing PF, poly (9,9-dioctylfluorene-2,7-diyl-alt-4,7-bis(3-hexylthien-5-yl)-2,1,3-benzothiadiazole-2,2-diyl) (F8TBT); carbazole-based conjugated polymers; and thiophene-based conjugated polymers, e.g. cyclopenta[2,1-b:3,4-b]dithiophene-based polymers.

For example, the photoactive composite may comprise a blend selected from MDMO-PPV:PCBM, MDMO-PPV:P3HT, F8TBT:PCBM, F8TBT:P3HT, APFO-3:PCBM and OC1C10-PPV:PCBM.

Alternatively, the photoactive composite may comprise a small molecule material, e.g. dimers, trimers and oligomers. The small molecule material may be selected from: metal phthalocyanines such as phthalocyanine zinc or phthalocyanine copper; fullerenes; oligothiophene; pentacene; and nanoparticle based systems such as nanoparticle-nanoparticle blends or nanoparticle-polymer blends comprising nanoparticles of CdSe, PbSe, PBS, PbTe, CdTe or ZnO.

The person skilled in the art will be aware of other suitable candidate materials for the photoactive composite. For instance, the invention may incorporate dye-sensitised photovoltaic cells such as solid state-type dye sensitised cells, ionic liquid-based dye sensitised cells or electrolyte-based dye sensitised cells in which the electrodes may be spaced relatively far apart, e.g. by a distance of several mm, say 2 to 5 mm.

The photoactive layer may comprise more than one photoactive composite. For instance, the phototactive layer may comprise a first photoactive composite arranged on top of a second photoactive composite, the first and second photoactive composites absorbing radiation of different ranges of wavelength.

Preferably, the means to control and/or regulate the operating temperature of the cell may comprise a light absorbent material, for example an infra-red absorbent material, for instance a plurality of infra-red absorbent particles or nanoparticles or to an infra-red absorbent dye. These materials will likely be non charge-generating absorbents.

The infra-red absorbent material may be electrically inactive, e.g. not photoactive.

Alternatively, the infra-red absorbent material be electrically active, e.g. it may be photoactive and may be polymeric. The infrared absorbent material will not (at least usually) create charge carriers in the spectral range of interest for increasing the cell temperature.

In preferred embodiments, the infra-red absorbent material may comprise a selective absorber. In this specification we consider the term “selective absorber” to be one that is characterised by a high absorbance in the solar spectrum (up to wavelengths of 3 micrometres) and high reflectance (low emittance) at longer wavelengths (Mid Infrared (3-8 micrometres) to long (8-15 micrometres) and far infrared). The selective absorber may be an intrinsic absorber, a semiconductor-metal tandem, a multilayer absorber, a multi-dielectric composite coating, a textured surface or a selectively transmitting coating on a blackbody-like absorber.

A suitable infra-red absorbent dye may be selected from: tetrakis amminium dyes, tris amminium dyes, dithiolene nickel dyes, dithiolene noble metal dyes, phthalocyanine dyes, anthraquinone dyes. Mixtures of these dyes and others may be chosen in order to absorb a broader spectrum of infra red radiation.

Suitable particles or nanoparticles may be based on silicas, silicates, phosphate, alumina or transition metal oxides. The particles or nanoparticles may be provided in a thin film, e.g. a CuMn-spinel thin film.

Other suitable infra-red absorbent materials may include: carbon black placed behind the photoactive layer, particularly where the photoactive layer is relatively thick; quantum dots; or tunable photonic structures.

In preferred embodiments, the infra-red absorbent material and photoactive composite may be selected such that there is minimal, or preferably no, overlap of their absorption spectra.

The infra-red absorbent material may be provided as or in a discrete layer within the cell, e.g. deposited to cover at least partially the front electrode or between the front and back electrodes. Alternatively, in embodiments in which the back electrode is at least partially transparent, the infra-red absorbent material may be provided behind, e.g. adjacent, the back electrode.

For instance, the discrete layer may comprise a CuMn spinel thin film.

Various techniques may be used to deposit the or each layer comprising the infra-red absorbent material. For example, the or each such layer may be laid down by electroplating or vapour deposition.

Preferably the infra-red absorbent material may comprise a surface coating applied to at least one of the electrodes, preferably the back electrode, e.g. a solution-chemical derived nickel-alumina coating.

Alternatively or additionally, the infra-red absorbent material may be dispersed within a component, e.g. at least part of any one or more layers, of the cell.

Alternatively or additionally, additional light absorbing chemical groups may be attached to the photoactive composite, e.g. covalently bonded to a semiconductor, which may be an organic semiconductor.

Where the infra-red absorbent material, e.g. particles, nanoparticles or dye, is dispersed within the photoactive layer, the infra-red absorbent material may be is present in an amount not exceeding 50% by volume of the photoactive layer. Preferably, the infra-red absorbent material may account for no more than 40%, preferably 30% or less, by volume of the photoactive layer.

Alternatively or additionally, the infra-red absorbent material may be dispersed within at least one of the electrodes, preferably the back electrode.

An electrode comprising PEDOT may provide a suitable matrix for an infra-red absorbent material to be dispersed therein.

Alternatively or additionally, oxides of metals such as oxides of chromium (e.g. Cr₂O₃, Cr(OH)₃ or CrO(OH) could serve as electrodes and at the same time absorb photons in the near infra-red range. Another alternative may be to provide a porous or nanostructured metal or metal oxide layer as part of at least one of the electrodes to absorb light in the specified spectral range. Such a porous or nanostructured layer may be combined with, e.g. planised by, a, preferably transparent, conducting or semiconducting component, e.g. PEDOT or ZnO.

Suitable transparent electrode materials include: ZnO, Cr, TiO₂, ITO, MeO/Ag/MeO as cathodes; and/or PEDOT:PSS as anodes. Other suitable materials and arrangements will be known to the person skilled in the art.

Advantageously, the infra-red absorbent material may be selected such that it absorbs radiation, the majority of which is of wavelengths that are not absorbed by the photoactive material. Preferably, the infra-red absorbent material may be selected such that it does not absorb radiation having wavelengths of more than 3 μm, as absorption at longer wavelengths may result in emittance and therefore in heat loss.

Accordingly, the beneficial effect of increasing the cell operating temperature may be achieved with minimal impact on the harvesting of photons by the photoactive material.

For example, Epolight™ 1117, one suitable dye with the tatrakis amminium structure, available from Epolin Inc. of Newark, N.J., USA, principally absorbs radiation with wavelengths of around 800 nm or more and its absorption maximum, λₘₐₓ, is at around 1070 nm. Accordingly, it may be used in a cell, in which the photoactive composite comprises P3HT:PCBM.

The infra-red absorbent material may be switchable, e.g. it may be activated by changes in temperature or an applied electric field. As such, the infra-red absorbent material may comprise an electrochromic or a thermochromic material.

Alternatively or additionally, the infra-red absorbent material may comprise a thermochronic ink that undergoes a transition from transparent to strongly coloured over a very small temperature range.

Alternatively or additionally, an absorber may be selected which absorbs photons in parts of the electromagnetic spectrum other than the infra-red region in order to increase the cell operating temperature. Ideally, there should be minimal, preferably substantially no, overlap between the absorption spectra of such an to absorber and of the photoactive composite.

For instance, a suitable absorber may comprise a thermochromic substance, e.g. an ink, which absorbs photons from the visible part of the electromagnetic spectrum and switches from being absorbent at low temperatures to transparent at higher temperatures, e.g. an ink comprising Leuco dye crystal violet lactone. Preferably, the appropriate Leuco dye is provided in the presence of acid and a dissociable salt in a solvent such as dodecanol. In order to be utilised, such a dye may be encapsulated into small, e.g. micron-sized, particles by a material that responds to a temperature change by changing its pH.

Other organic materials, e.g. comprising the molecule lophine, which have been shown to switch from transparent to opaque in the infra-red region of interest, may also be suitable.

The light absorbent material may be chosen to absorb light in an area of the visible spectrum in which the photoactive material has a zero or low absorption characteristic. Ideally, the light absorbent material and photoactive material can be matched so as to provide the cell with a dark or black appearance. This will be beneficial in terms of planning and siting cells. As such a further aspect of the invention relates to an organic photovoltaic cell having a black or dark appearance.

The in-use operating temperature of the cell may be regulated and/or controlled at a temperature at or above ambient temperature. The in-use operating temperature of the cell may be regulated and/or controlled at a temperature of from 20 to 70° C., e.g. 25 to 70, 30 to 70, 30 to 65 or 60 or 55 or 50, 35 to 65 or 60 or 55 or 50, 40 to 65 or 60 or 55 or 50° C.

The means to control and/or regulate the operating temperature of the cell may additionally or alternatively comprise means adapted to limit or reduce convection from the cell, e.g. by reducing the wind speed close to the cell, such as thermal insulation and/or convection barriers.

For instance, an insulation layer may be provided around some or all of the cell, preferably to provide an air gap between the insulation layer and the cell.

Any portions of the insulation layer which cover the front electrode of the cell should be transparent. Accordingly, the insulation layer may comprise a transparent panel made from glass or a plastics material such as PET, PMMA or polycarbonate.

Alternatively or additionally, structures or formations may be provided to shelter the cell by obstructing or diverting the wind, which would otherwise impinge upon the cell to cool it. This approach has the advantage that no light has to pass through a transparent plate, in use, where absorption and reflectance losses may occur.

For instance, a series of upstanding structures, may be provided. The structures may comprise various shapes including lamellar structures and/or hexagonal structures.

Preferably, the structures may be located in front of the cell, in which case they should be transparent or reflective so as not to obstruct or inhibit the passage of electromagnetic radiation into the cell.

Additionally or alternatively, the means to control and/or regulate the operating to temperature of the cell may comprise a reflecting, e.g. an infra-red reflecting, material actuatable to prevent the operating temperature rising to above the optimum range, e.g. an infra-red reflecting thermochrome, which may be a vanadium dioxide-based material. The vanadium dioxide-based or other appropriate material may be “switched on” at a temperature in the range of 60-70° C. Alternatively or additionally, infra-red reflecting electrochromic materials may be used.

The infra-red reflecting material may comprise a thermochronic polymer opal, e.g. as reported by Sussman et al Appl Phys Letts 95, 173116 (2009), or other photonic crystal structures such as metal elastomer nanovoids which may respond to temperature changes, e.g. as reported by Cole et al App Phys Letts Vol. 95, 154103 (2009).

Certain organic thermochronic materials, have also been shown to be very efficient infra-red reflectors, e.g, as reported by Karlessi et al Solar Energy Vol. 83, Issue 4, April 2009, Pages 538-551).

In order that the invention may be more readily understood, it will now be described by way of example only with reference to the accompanying drawings, in which:

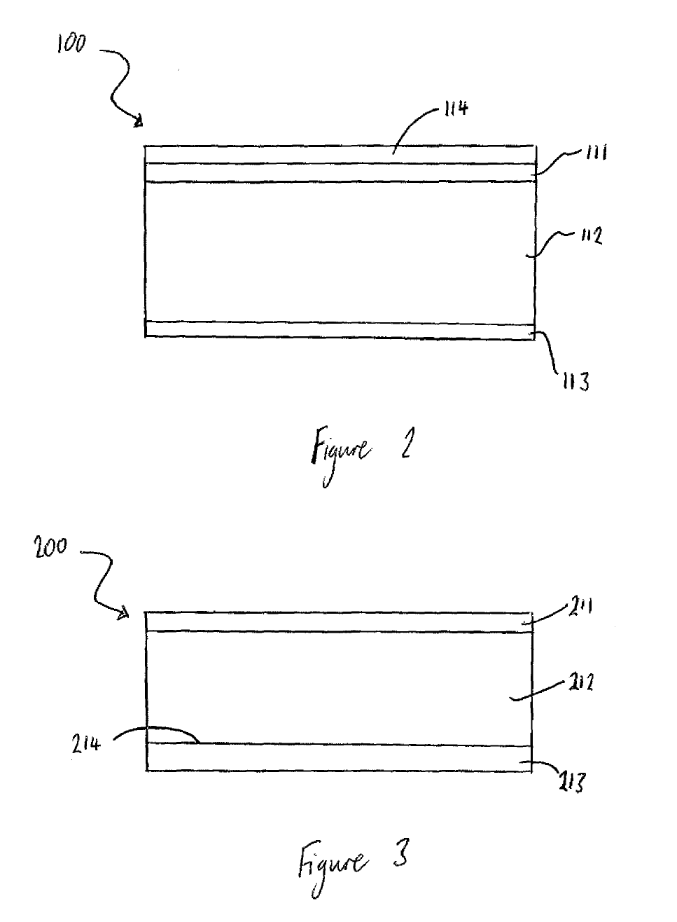

FIG. 2 shows a cross-section of a first embodiment of a photovoltaic cell according to the invention;

FIG. 3 shows a cross-section of a second embodiment of a photovoltaic cell according to the invention;

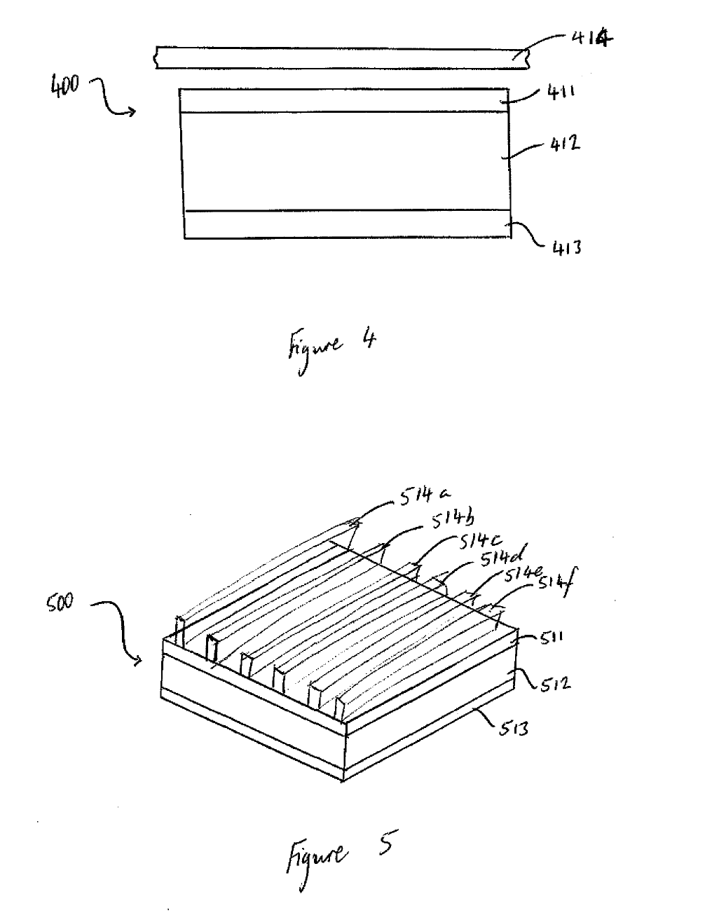

FIG. 4 shows a cross-section of a third embodiment of a photovoltaic cell according to the invention; and

FIG. 5 shows a perspective view of a fourth embodiment of a photovoltaic cell according to the invention.

Certain solar cells exhibit increased efficiency at higher temperatures. We understand that this a consequence of the fact that the principal mode of charge carrier transport in organic semiconductors is via a thermally activated hopping process. Hence, without wishing to be bound by any particular theory, at higher temperatures, there may be an increase in the short circuit current and the fill factor. The fill factor is defined by the product of current density and voltage at the maximum power point divided by the product of open circuit voltage and short circuit current density.

The increases in the short circuit current and the fill factor may outweigh the effect of the decrease in the open circuit voltage which accompanies the increase in temperature, thereby resulting in an improved power conversion efficiency.

The operating temperature of a solar cell or module can be modelled empirically. For example, an energy balance model has been developed (Mattei et al (2006), “Calculation of the polycrystalline PV module temperature using a simple method of energy balance”, Renewable Energy 31(4), 553-567) according to which:—

$${T}_{c} = \frac{aT ϕ - n ϕ}{{U}_{pv}} + {T}_{a} \qquad [ 1 ]$$

where T_{c} is the cell operating temperature, Tₐ is the ambient temperature, α is the absorption coefficient of the cell, τ is the transmittance of the cover of the cell, η is to the cell's power conversion efficiency, φ is the solar irradiance and Uₚᵥ is a heat exchange coefficient.

The operating temperature of a photovoltaic cell or module in situ is primarily determined by a combination of environmental parameters, in particular light intensity, wind speed and direction and ambient temperature, and by the physical properties of the cell or module, e.g. the absorption coefficient of the cell and its power conversion efficiency.

For instance, a significant correlation between air temperature and change in electrical power can be made from outdoor measurements on organic solar cells presented by Konarka. From these measurements it can be derived that the power conversion efficiency changes by 20% with a variation in air temperature from 0° C. to 30° C.

Wind speed and direction affect heat transfer from the cell or module by convection, thereby influencing the cell operating temperature.

Experiments by the applicant have demonstrated the effect of convection on the cell operating temperature.

In these experiments, an inverted P3HT:PCBM solar cell was equipped with a PT100 temperature sensor. The cell was exposed to sunlight when located outside and inside behind a closed window. The amount of convection was altered inside using a ventilator having two power settings (I and II) or outside at different wind speeds.

On the day the experiments were carried out, the weather was sunny with a few clouds and a slight breeze. The solar irradiation was primarily direct and had an intensity in the region of 100 mWcm⁻². The ambient temperature indoors was approximately 23.8° C.

The results of the experiments are shown in Table 1 below.

TABLE 1
Results from experiments demonstrating the effect of convection on the
cell operating temperature

| Light Intensity | Light Intensity | Cell | |
|---|---|---|---|
| Inside | Outside | Temperature | Operating |
| (mWcm⁻²) | (mWcm⁻²) | (° C.) | Conditions |
| 67.0 | 99.7 | 49.6 | Inside closed window |
| 74.5 | 98.0 | 50.1 | Inside closed window |
| 73.9 | 101.0 | 50.1 | Inside closed window |
| 73.5 | 101.6 | 50.8 | Inside closed window |
| 69.6 | 98.4 | 32.4 | Inside closed window |
| | | | ventilator 1 |
| 73.9 | 100.7 | 30.8 | Inside closed window |
| | | | ventilator II |
| — | 99.3 | 44.6 | Outside |
| — | 99.7 | 37.5 | Outside elevated |
| | | | breeze |

Inside, the cell temperature reaches around 50° C., i.e. close to the optimum operation temperature for this type of semiconductor composite, at a light intensity of approximately 70 mWcm⁻². From the data in Table 1, it can be seen that enforced convection, i.e. using the ventilator, resulted in a decrease in cell temperature of almost 20° C. which amounts to a reduction in efficiency of approximately 13% (assuming a temperature coefficient of efficiency of 0.66% ° C.⁻¹).

The effect of changes in wind speed can be predicted using the empirical model to above.

Values for Uₚᵥ are available in the literature. According to some studies (Mattei et al (2006), “Calculation of the polycrystalline PV module temperature using a simple method of energy balance,” Renewable Energy 31(4), 553-567; Sandnes and Rekstad (2002), “A photovoltaic/thermal (PV/T) collector with a polymer absorber plate. Experimental study and analytical model,” Solar Energy 72(1), 63-73), Uₚᵥ will be in the range of 39.9-42.2 W° C.⁻¹ m⁻² for a wind speed of 4 ms⁻¹ and 17.1 W° C.⁻¹ m⁻² or 11.3 W° C.⁻¹ m⁻² for an effective wind speed of 0 ms⁻¹.

If we also assume the following values for the other terms in equation 1—Tₐ=20° C., φ=850 mWcm⁻², and α=60%—then, depending on the value of Uₚᵥ selected, an increase in T_{c} of between 8° C. and 23° C. and as a consequence an increase in η of around 5-15% (assuming an efficiency temperature coefficient of around 0.66% ° C.⁻¹) may be predicted for a drop in wind speed from 4 ms⁻¹ to 0 ms⁻¹.

It is envisaged that predictions such as this should be valid as long as T_{c} remains below the optimum cell operating temperature, e.g. around 50° C.

Therefore, a further consideration may be necessary, namely to prevent overheating of the cell. This may be especially important in relation to the operation of solar cells in environments with large variations in temperature, wind speed (and direction) and irradiation.

There is shown in FIG. 2 an organic photovoltaic cell 100 comprising a layered structure. The layered structure includes an infra-red absorbent layer 114, underneath which is located a transparent front electrode 111, a photoactive layer 112 and a reflective rear electrode 113.

The front electrode 111 and rear electrode 113 are of conventional design and comprise PET/ITO and PEDOT respectively.

The photoactive layer 112 is around 100-250 nm thick. It comprises P3HT:PCBM as the photoactive composite.

The infra-red absorbent layer 114 includes Epolight™ 1117, an infra-red absorbent dye, deposited on to the front electrode 111.

FIG. 3 shows a second embodiment of a photovoltaic cell 200 according to the invention. The cell 200 comprises a layered structure having a transparent front electrode 211 comprising PET/ITO and a back electrode 213 comprising PEDOT between which is disposed a photoactive layer 212.

The photoactive layer is around 250 nm thick and comprises P3HT:PCBM as the photoactive composite.

In the embodiment shown in FIG. 3, infra-red absorbance is provided by a surface coating 214 applied to the back electrode 213.

Often, the back electrode of a photovoltaic cell is reflective so as to boost absorption (“harvesting”) of photons by causing incident light to pass back through the photoactive layer.

The provision of an absorbent surface coating on the back electrode to increase the cell operating temperature generally will be most beneficial when the majority of to absorption by the photoactive layer occurs in the first pass of the incident light therethrough, in which case the benefits associated with increasing the operating temperature may outweigh any negative effects of any reduction in reflectivity of the back electrode, due to the coating.

Furthermore, in cases where the majority of photon absorbance occurs in the first pass through the photoactive layer, the infra-red absorbent material located therebelow, e.g. surface-coated on the back electrode, may be elected from a broader range of materials, since it is less important that any overlap of the absorption spectra of the infra-red absorber and the photoactive layer is minimised.

For instance, where the infra-red absorbent material is located behind the photoactive layer, in particular when the photoactive layer comprises a photoactive composite that is highly absorbent, inorganic materials as used for solar thermal conversion may be utilised. Suitable materials may include electroplated black chrome, Cr—Cr₂O₃ cermet, nickel pigmented anodic Al₂O₃ and titanium nitride. These materials may be preferred, since they may be particularly effective selective absorbers.

In embodiments where the back electrode is at least partially transparent, an infra-red absorbent material may be provided behind the back electrode. For instance, the infra-red absorbent material may be deposited on to a rear face of the back electrode. Such embodiments may comprise a rear reflector located behind the back electrode, e.g. the or a substrate or a part thereof may be reflective.

FIG. 4 shows a third embodiment of an organic photovoltaic cell 400 according to the invention.

The cell 400 comprises a layered structure containing a transparent front electrode 411, a back electrode 413 and a photoactive layer 412 between the front electrode 411 and the back electrode 413.

In front of the front electrode 411 is a front insulation panel 414. There is an air is gap between the front electrode 411 and the insulating panel 414. The air gap helps to insulate the cell 400. Preferably, the insulation panel 414 is provided with an anti-reflection coating.

The insulation panel 414 and the air gap it maintains have the effect of reducing heat loss caused by convection, thereby helping to maintain or increase the operating temperature of the photovoltaic cell 400.

The insulation panel 414 needs to be transparent so as not to interfere with the passage of electromagnetic radiation into the photoactive layer 412. Accordingly, the insulating panel 414 may be made from glass or a transparent plastics material such as PET, PMMA or polycarbonate.

The insulation panel may be relatively thin, e.g. less than 1 cm, preferably no more than 0.5 cm, thick.

Additionally or alternatively, insulation panels or layers may be provided around the sides of and/or behind the photovoltaic cell or module. In such locations, of course, there is no requirement for the insulation material to be transparent.

FIG. 5 shows a fourth embodiment of an organic photovoltaic cell 500 according to the present invention.

The cell 500 comprises a transparent front electrode 511, a back electrode 513 and a photoactive layer 512 between the front electrode 511 and the back electrode 513.

Extending upwardly from the front surface of the front electrode 511 is a series of lamellar protrusions 514a-f, arranged in parallel with each other and extending across the cell 500.

The protrusions 514 a-f act to reduce the wind speed close to the surface of the cell 500, thereby reducing the rate of convection from the cell 500 and consequently helping to maintain or increase the cell operating temperature.

The lamellar protrusions 514a-f are transparent. Alternatively, they may be highly reflective. Either way, unwanted absorption losses may be minimised.

It is envisaged that the provision of formations such as lamellar protrusions to reduce wind speed may be preferable to the provision of a front insulating panel, as the additional absorption losses that may occur will typically be less.

In the most preferred embodiments of the invention, the organic photovoltaic cell may be adapted such that any increase in the operating temperature may be arrested at least partially when it reaches a given value in order to ensure that the cell operates within or close to its optimum efficiency range.

For example, an infra-red reflective material that “switches on” at a given threshold temperature such as a reflective thermochromic material may be incorporated within the cell, e.g. in a front insulating panel, as a discrete layer dispersed within the photoactive layer or as a surface coating. Vanadium dioxide-based materials may be preferred, in particular, substoichrometric vanadium dioxide.

For instance, a coating containing a vanadium dioxide material may be provided on a glass or transparent plastic surface of the cell, e.g. on an insulating panel or on a surface of a transparent electrode.

In addition, or as an alternative, where the cell or module is provided with insulation or formations designed to reduce wind speed, these may be designed so as to be self regulating.

For instance, the insulating layer may be removed automatically when the operating temperature of the cell reaches a particular value.

In other embodiments, the formations may be adjustable to adapt to different wind directions. For instance, the angle of the lamellar protrusions 514a-f and/or the distance between the insulating panel 414 and the front electrode may be variable with the operating temperature of the cell.

The position and angle of the structures may be controllable such that they do not cause shading of the solar module as the incident angle of the sun changes during the day.

It will be appreciated that a cell or module according to the invention may comprise any combination of the various means to regulate and/or control the cell operating temperature described or otherwise disclosed herein.

It will also be appreciated that the invention allows improved operation of photovoltaic cells and modules in locations, where previously climatic conditions may have affected operation to such an extent as to discourage installation, e.g. on economic grounds.

Further, it will be appreciated that the means to regulate and/or control the cell operating temperature disclosed herein may be suitable for use with inorganic photovoltaic cells. In particular, the performance of amorphous inorganic photovoltaic cells, e.g. cells comprising amorphous silicon as the photoactive composite, may benefit from temperature regulation and/or control in accordance with the present invention. Amorphous silicon photovoltaic cells may exhibit temperature-dependent behaviour similar to organic photovoltaic cells.

Photovoltaic cells or modules comprising such cells according to the invention may be incorporated within electronic devices, e.g. handheld or portable devices.

Modules comprising cells according to the invention may also find utility in solar power stations or in more localised microgeneration applications, e.g. to provide electricity for isolated permanent or semi-permanent structures that are not connected to the electricity grid or they may be installed on or around pre-existing or new-build residential, commercial or industrial buildings.

The invention further encompasses methods of manufacture and use of the photovoltaic cells described or otherwise disclosed herein.

1. A photovoltaic cell, the cell comprising a photoactive layer provided between electrodes, and means to increase the in-use operating temperature of the photoactive layer to provide a photovoltaic cell which is adapted to operate within or towards optimum power conversion efficiency in a variety of environmental and/or climatic conditions.

2. A cell according to claim 1, wherein the cell comprises a layered structure including a transparent front electrode and a back electrode with the photoactive layer therebetween.

3. A cell according to claim 1, wherein the photoactive layer is a composite which comprises a blend selected from the group consisting of a plurality of conjugated polymers; one or more conjugated polymers and one or more fullerene derivatives; small molecule(s) and fullerene(s); conjugated polymer(s) and nanoparticles; fullerene(s) and nanoparticle(s); and different types of nanoparticles.

4. A cell according to claim 1 wherein the means to increase the in-use operating temperature of the photoactive layer comprises a non charge generating photon absorbing material.

5. A cell according to claim 4, wherein the non charge generating photon absorbing material absorbs light with a wavelength of 600 nm or greater.

6. A cell according to claim 4, wherein the non charge generating photon absorbing material is an infra-red absorbent material.

7. A cell according to claim 4, wherein the non charge generating photon absorbing material comprises radiation absorbent particles or nanoparticles or a dye.

8. A cell according to claim 4, wherein the non charge generating photon absorbing material is provided as or in at least one discrete layer within the cell.

9. A cell according to claim 4, wherein the non charge generating photon absorbing material is dispersed within at least one component of the cell.

10. A cell according to claim 5, wherein the non charge generating photon absorbing material is switchable.

11. A cell according to claim 2, wherein the back electrode is at least partially transparent and at least a portion of a photon absorbing material is provided behind the back electrode.

12. A cell according to claim 1, wherein the means to increase the in-use operating temperature of the photoactive layer comprises means adapted to limit or reduce convection from the cell.

13. A cell according to claim 1, wherein an insulation layer is provided around some or all of the cell to provide an air gap between the insulation layer and the cell.

14. A cell according to claim 1, wherein structures or formations are provided to shelter the cell by obstructing or diverting wind, which would otherwise impinge upon the cell to cool it.

15. A cell according to claim 14, wherein the structures or formations are located in front of the cell and are each either transparent or reflective.

16. A cell according to claim 14, wherein the structures or formations comprise lamellar, hexagonal, rectangular structures.

17. A cell according to claim 14, wherein the position and angle of the structures or formations is controllable such that they do not cause shading of a solar module as an incident angle of the sun changes during the day.

18. A cell according to claim 1, wherein the means to increase the in-use operating temperature of the photoactive layer comprises a material switchable from transparent to reflective in a certain wavelength range in an absorption range of an absorber material to prevent the operating temperature exceeding an optimum range.

19. A cell according to claim 18, wherein the reflecting material comprises an infra-red reflecting thermochromic or electrochromic material.

20. A cell according to claim 18, wherein the reflecting material comprises a vanadium dioxide-based material.

21. (canceled)

22. A cell according to claim 1, wherein the photoactive layer comprises amorphous silicon.

23. A cell according to claim 22, comprising a component arranged to absorb light in an area of the visible spectrum in which the photoactive material has a zero or low absorption characteristic so as to provide the cell with a dark or black appearance.

24. (canceled)

25. A method of operating a photovoltaic cell, the method comprising causing the in-use operating temperature of the cell to increase to improve an efficiency of the cell which is adapted to operate within or towards optimum power conversion efficiency in a variety of environmental and/or climatic conditions.

26. A method according to claim 25, comprising controlling and/or regulating the in-use operating temperature of the cell to a temperature of from 30 to 65° C.

27. A cell according to claim 1, comprising a component arranged to absorb light in an area of the visible spectrum in which the photoactive material has a zero or low absorption characteristic.

28. A cell according to claim 1, wherein the means to increase the in-use operating temperature of the photoactive layer comprises a means adapted to limit or reduce convection from the cell; and a material switchable from transparent to reflective in a certain wavelength range in an absorption range of an absorber material to prevent the operating temperature exceeding an optimum range.

29. A cell according to claim 1, wherein the photoactive layer has a positive temperature co-efficient of efficiency at an ambient temperature Ta of 20° C.
